(19) United States
(12) Patent Application Publication
(10) Pub. No.: US 2003/0067314 A1
(43) Pub. Date: Apr. 10, 2003

(54) Testing arrangement and testing method

(76) Inventor: Pekka Kaukko, Oulu (FI)

Correspondence Address: FINNEGAN, HENDERSON, FARABOW, GARRETT &, DUNNER LLP, 1300 I STREET, NW, WASHINGTON, DC, 20006, US

(21) Appl. No.: 10/203,183

(22) PCT Filed: Feb. 12, 2001
(86) PCT No.: PCT/FI01/00125

(30) Foreign Application Priority Data
Feb. 11, 2000 (FI) 20000292

(51) Int. Cl. G01R 31/02

(52) U.S. Cl. 324/754

(57) ABSTRACT

The invention relates to a testing arrangement which comprises a connection (2) to be tested comprising one or more analogue components (11, 12). According to the invention, to test one or more analogue components of the connection (2) the testing arrangement comprises a Boundary Scan-type digital component (21) which comprises one or more contact elements (31 to 33), and through one or more contact elements, the Boundary Scan digital component (21) is connected to the connection (2) being tested so that by means of an internal digital Boundary Scan control line (41) of the Boundary Scan digital component (21) and controlled by a controller (51) in the testing arrangement, a voltage-level control according to a digital logic value can be provided in at least one location to the connection (2) being tested comprising one or more analogue components. The arrangement also comprises a measuring instrument (60) which measures the connection (2) being tested comprising one or more analogue components and the Boundary Scan-type digital component connected to it, for the purpose of measuring the impact of the voltage-level control directed to the connection being tested. The arrangement further comprises a means (70) for analysing the measurement information of the measuring instrument (60), which determines a testing result concerning one or more analogue components of the connection on the basis of the measurement information of the measuring instrument (60).

### FIELD OF THE INVENTION

The invention relates to a testing arrangement comprising a connection to be tested, which comprises one or more analogue components.

The invention also relates to a testing method for testing a connection comprising one or more analogue components.

### BACKGROUND OF THE INVENTION

The present invention relates to testing a connection containing analogue components.

Testing the operation of connections containing electronic components is necessary to ensure the operation of devices. This is done by what is known as ICT testing (In Circuit Testing), a procedure directed to a device under test DUT in which the connection to be tested is. To test the digital components in the connection, it is possible to use a Boundary Scan-type digital component conforming to a standard, which, in addition to the normal structural parts of a digital component, also has a digital control line through which a digital pulse train used in testing is obtained to the connecting elements of the Boundary Scan-type digital component, to which a second digital component to be tested is connected. Boundary Scan-type digital components equipped with a digital control line are available as the following components, for instance: ASIC circuits (Application Specific Integrated Circuit), gate circuits, DSP processors and programmable logic circuits.

A separate standard also exists, which relates to a Boundary Scan component having not only a digital control line but also an analogue measuring line, but the availability of components of the above type is poor, and due to their structure, they are expensive special components.

A bed of nails therefore still needs to be used in testing connections containing analogue components, this having the drawback that the use of a bed of nails requires exact positioning action, and an additional drawback is that as the component density of connections increases, it is difficult or impossible to fit the nails of the bed into the places where they should be connected to the connection; it is impossible especially in the case of a BGA, i.e. Ball Grid Array, package type in which the soldered joints are underneath the component against the circuit board.

It is known that to reveal short-circuits and breaks in connections containing digital components, the testing arrangement disclosed in Fl 100829 can be used, but it cannot reveal matters concerning analogue components, such as whether the connection has a resistor having just the correct resistance.

### BRIEF DESCRIPTION OF THE INVENTION

It is thus an object of the invention to implement a testing arrangement and a testing method so as to perform the testing of an analogue connection easily and reliably.

This is achieved by a testing arrangement of the invention, which is characterized in that to test one or more analogue components of a connection, the testing arrangement comprises:

a Boundary Scan-type digital component which comprises one or more contact elements, and through one or more contact elements the Boundary Scan digital component is connected to the connection being tested so that by means of an internal digital Boundary Scan control line of the Boundary Scan digital component and controlled by a controller in the testing arrangement, a voltage-level control according to a digital logic value can be provided to the connection being tested comprising one or more analogue components in at least one location,

a measuring instrument which measures the connection being tested comprising one or more analogue components and the Boundary Scan-type digital component connected to the connection for the purpose of measuring the impact of the voltage-level control directed to the connection being tested, and

a means for analysing the measurement information of the measuring instrument, which determines a testing result concerning one or more analogue components of the connection on the basis of the measurement information of the measuring instrument.

The testing method of the invention is characterized by

using a Boundary Scan-type digital component which comprises one or more contact elements, through which one or more contact elements, the Boundary Scan digital component is connected to the connection being tested,

providing by means of an internal digital Boundary Scan control line of the Boundary Scan digital component a voltage-level control according to a digital logic value to the connection being tested comprising one or more analogue components in at least one location through at least one contact element,

measuring the connection being tested comprising one or more analogue components and the Boundary Scan-type digital component connected to the connection for the purpose of measuring the impact of the voltage-level control directed to the connection being tested, and

analysing the measurement information and determining one or more testing results concerning one or more analogue components of the connection on the basis of the measurement information.

The invention is based on using a conventional Boundary Scan-type digital component, i.e. one equipped with a digital control line only, to assist in testing analogue components. By means of the digital control line of the Boundary Scan-type digital component, the contact elements of the Boundary Scan component are given a logical 0 or a logical 1, which the analogue connection sees for instance as a 5V voltage, in the case of the logical state 1, and as a 0V voltage value, in the case of the logical value 0. The impact of the digital logic-value control seen by the analogue connection as a voltage-level control and provided by the control line is monitored by current measurement or other measurement, from which a testing result concerning an analogue component of the connection being tested is determined. The Boundary Scan component can be seen as a component providing a testing input.

The testing arrangement and method of the invention provide several advantages. By means of the invention, the use of a bed of nails can be avoided, thus avoiding the above-mentioned drawbacks. A conventional Boundary Scan digital component having only a digital control line can be used in the invention, thus avoiding the use of an expensive Boundary Scan component having a special structure, i.e. one which in addition to a digital control line also has an analogue measuring line, this component having the additional problem of being poorly available. The conventional Boundary Scan-type component, i.e. one equipped with only a digital control line, used in the invention is a mass-production component and consequently, its price is reasonable and its availability is good. The invention is quick and easy to use.

### BRIEF DESCRIPTION OF THE FIGURES

In the following, the invention will be described in greater detail by means of preferred embodiments and with reference to the accompanying drawings in which

FIG. 1 shows a first embodiment of the invention in which the Boundary Scan digital component is on the same connection base as the connection being tested comprising analogue components,

FIG. 2 shows a second embodiment of the invention in which the Boundary Scan digital component is through a connector connected to a connection comprising analogue components and residing on a different connection base.

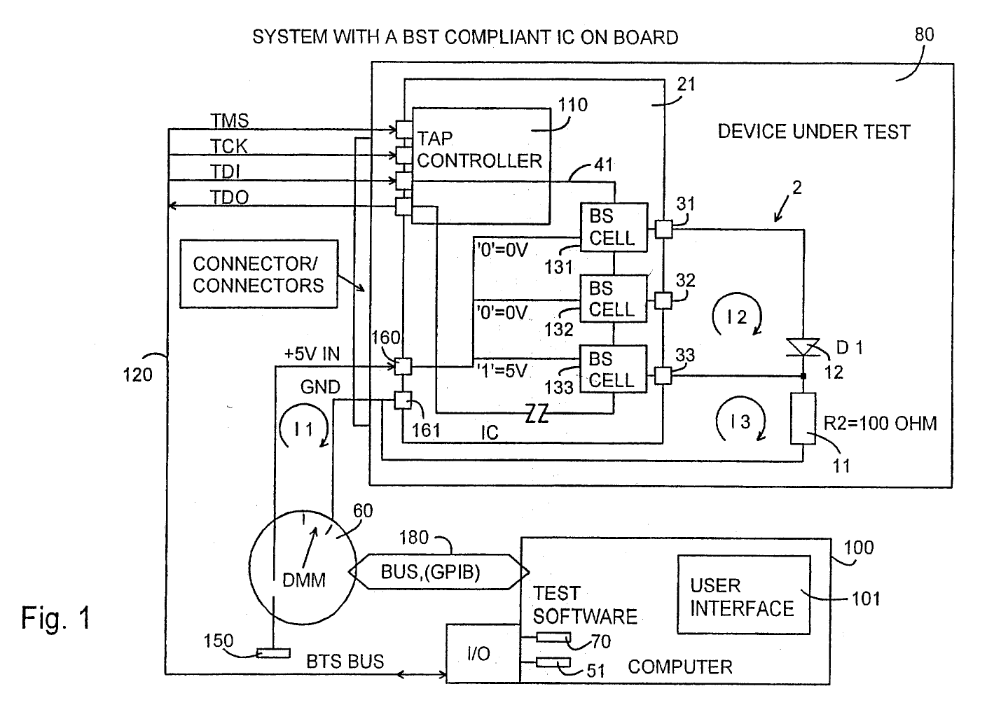

With reference to FIG. 1, the invention relates to a testing arrangement 1 which comprises a connection 2 to be tested comprising one or more analogue components 11 to 12. In a preferred embodiment, at least one analogue component of the connection is a diode D1, 12, a resistor R2, 11, or a coil or capacitance, for instance. The analogue components of the connection, or at least a part of them, are preferably passive components. At least one component is preferably a component comprising one or more semiconductor barrier layers, for instance a diode or transistor.

To test one or more analogue components 11 to 12 of the connection 2, the testing arrangement comprises a Boundary Scan-type digital component 21 which comprises contact elements 31 to 33, and through one or more of the contact elements, the Boundary Scan digital component 21 is connected to the connection 2 being tested so that by means of an internal digital Boundary Scan control line 41 of the Boundary Scan digital component 21 and controlled by a controller 51 in the testing arrangement, a voltage-level control according to a digital logic value can be provided to the connection 2 being tested comprising one or more analogue components 11 to 12 in at least one location. The testing arrangement also comprises a measuring instrument 60 which measures the connection 2 being tested comprising one or more analogue components 11 to 12 and the Boundary Scan component 21 connected to it for the purpose of measuring the impact of the voltage-level control directed to the connection 2 being tested. The testing arrangement further comprises a means 70 for analysing the measurement information of the measuring instrument 60, which determines a testing result concerning one or more analogue components 11 to 12 of the connection 2 on the basis of the measurement information of the measuring instrument 60. In a preferred embodiment, the measuring instrument is a current meter 60, implemented by a DMM (Digital Multi Meter), for instance.

In a preferred embodiment, the Boundary Scan digital component 21 is an integrated circuit. In FIG. 1, the Boundary Scan digital component 21 is on the same connection base 80 as the connection 2 being tested. In such a case, the structure is integrated.

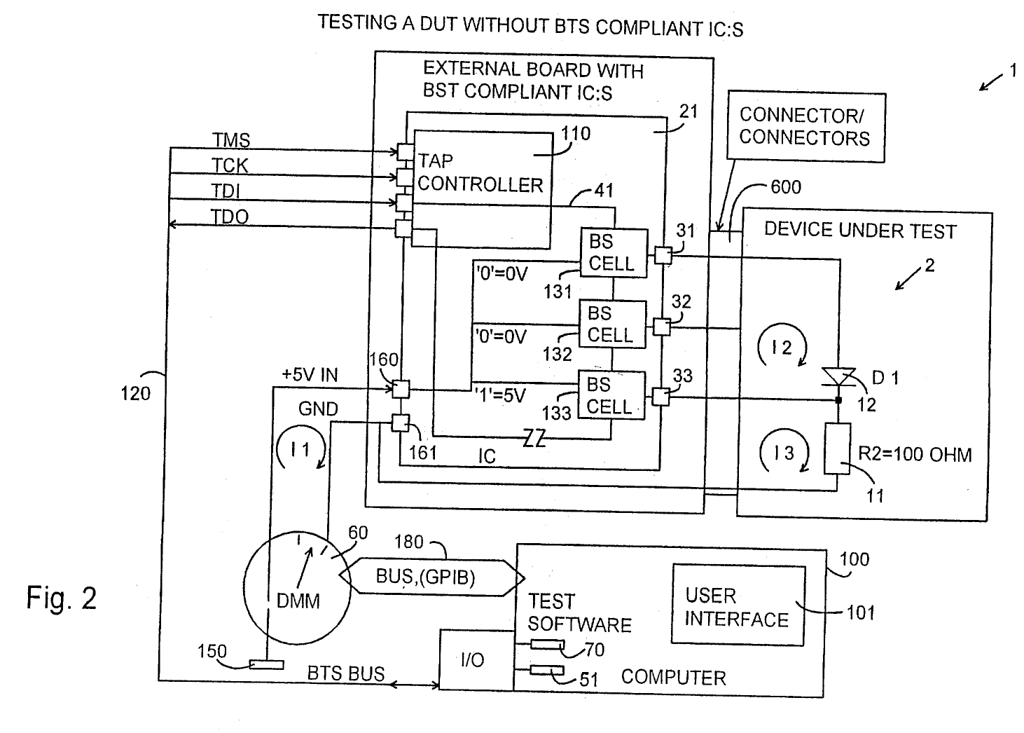

In a second embodiment of the invention in FIG. 2, the Boundary Scan digital component 21 and the connection 2 being tested are on different connection bases 90 and 91. This allows the replacement of the parts to be connected when necessary. The Boundary Scan digital component 21 is connected to the connection 2 being tested through a coupler 600, the coupler 600 is preferably a connector structure.

Concerning the embodiment of FIG. 1, it can be especially noted that in the preferred embodiment, the Boundary Scan-type digital component 21 and the connection 2 being tested comprising one or more analogue components belong to one and the same functional connection entity. In such a case, the Boundary Scan-type digital component 21 is not only meant for testing the analogue connection 2, but the Boundary Scan-type digital component 21 has a functional connection to the analogue connection 2.

In FIGS. 1 and 2, the testing arrangement comprises a computer or a corresponding control device 100 running a testing software. In FIGS. 1 and 2, the computer or control device 100 in question comprises a user interface 101 which can be a keyboard or any suitable user interface. The user interface 101 can also be an interface to an external device. In a preferred embodiment of the invention, the controller 51 performing the voltage-level control is a controller external to the Boundary Scan-type digital component 21 and preferably connected to the above-mentioned control device 100. In a preferred embodiment, the Boundary Scan-type digital component 21 comprises an internal controller 110 to which the internal digital Boundary Scan control line 41 is connected, and in this embodiment, the internal controller 110 in question is connected to the external controller 51. There is a transmission link, such as a BST bus 120, between the external controller 51 and the internal controller 110. The internal controller 110 of the Boundary Scan-type digital component 21 is a TAP (Test Access Port) controller. The data transmission link 120, such as a BST bus, is a data transmission bus in which the at least 4 different information sections presented in FIGS. 1 and 2 are transmitted. The first information section TMS is a Test Mode Selection. The second information section TCK is a clock pulse which controls the transmission of information. The third information section is TDI, i.e. Test Data In. The fourth information section is TDO, i.e. Test Data Out. The information section TDI is the actual control data whose bits affect the voltage level of the corresponding contact elements 31 to 33, which with a bit value 1 is 5V and with a bit value 0 is 0V.

The Boundary Scan component 21, which has contact elements 31 to 33, comprises Boundary Scan cells 131 to 133. The internal control line 41 of the Boundary Scan component 21 runs from the Test Data In interface in the internal controller 110 through said Boundary Scan cells 131 to 133 back to the internal controller 110, i.e. TAP controller 110, and to its Test Data out interface. Concerning the operation and internal structure as well as a more detailed description of the Boundary Scan components, reference is made to the publication “Boundary-Scan Test, A Practical Approach,” by Bleeker, van den Eijnden and de Jong, which is incorporated into this description of the present invention.

Concerning the control of the control line 41, it is further noted that according to a preferred embodiment, it is also possible that the controller of the testing arrangement, such as 51 above, performing the voltage-level control, is an internal controller of the Boundary Scan-type digital component, such as 110 above. In such a case, functions of the external controller 51 shown in the figures would be integrated into the internal controller 110 which would then no longer need the external control shown in the figures.

The operating voltage +5V required by the Boundary Scan digital component 21 is fed from the voltage source 150, or a corresponding power source, of the testing arrangement to an interface 160 of the Boundary Scan digital component 21, and correspondingly, a ground potential connection GND is connected to an interface 161 of the Boundary Scan digital component 21. Operating voltage is connected to the cells 131 to 133. The source 150 can also be in the measuring instrument 60.

Concerning the testing of the analogue component 11, i.e. resistor R2, in the connection 2 being tested, it can be noted that this is preferably an at least two-step control operation.

Step A is such that controlled by the controller 51 at a pace defined by the clock pulse TCK, a pulse comprising three zeros 000 is transmitted to the Boundary Scan component 21 through the control line 41. The leftmost bit, i.e. the first bit, i.e. the bit controlling the voltage level of the farthest contact element 33, is thus 0. The resistor R2, i.e. analogue component 11, then receives through the contact element 33 a voltage of 0 volt which corresponds to the same potential level as the grounding of one end of the component 11, R2 in point 161. The current meter 60 then measures a current generated only by a current l1, i.e. the current consumption of the BS component 21. The measuring result is transmitted through bus 180 or another transmission link to the computer 100 or another device in which the means 70 analysing the measurement information resides.

In step B, the control unit 51 begins to transmit to the Boundary Scan component 21 at a pace defined by the clock pulse TCK a control pulse 001 whose first bit is the logical value 1 which corresponds to a 5V voltage, for instance, and the second and third bits are 0 corresponding to a 0V voltage, for instance. Because the other end of the component 11, i.e. resistor R2, is in the ground potential GND, there is a 5V voltage over the resistor 11 producing a current l3 of a certain size through the component 11, i.e. resistor R2. The current meter 60 measures the sum current of the currents l3 and l1 and transmits it over the transmission path 180 to the computer or another device 100 in which the means 70 analysing the measurement information resides.

Finally, the means 70 determines on the basis of the change between the current measurements according to steps A and B, preferably on the basis of the difference, whether the component 12, i.e. R2, is in order. The means 70 can be a program, a processor, a separate component implementation, a combination of the above or the like. The same applies to the control device 100.

The execution order of steps A and B is not significant.

The two-step method described above can at a more general level be presented in such a manner that in a preferred embodiment, the internal digital Boundary Scan control line 41 of the Boundary Scan-type digital component 21 is arranged to provide the connection being tested as a logical value a voltage-level control of a first type, for instance 0V (bit value 0), during which the meter 60, preferably a current meter, is arranged to measure a first measurement value, preferably the current value l1. In addition, the control line 41 is arranged to provide a voltage-level control of a second type, for instance 5V (bit value 1), which differs from the voltage-level control of the first type and during which the meter 60, preferably a current meter, is arranged to measure a second measurement value, preferably the current value l1+l3. The means 70 analysing the measurement information of the meter 60, preferably a current meter 60, is arranged to define a testing result concerning one or more analogue components 11, 12, i.e. D1, R2, on the basis of the change, preferably the difference Δl=l3, between the measurement values. Either the current consumption of the BS component 21 only or the total current consumption of the BS component 21 and the analogue component is thus measured by means of the control pulse of the control line 41 of the BS component 21.

If the analysing means 70 or some other part of the testing arrangement knows in what size range the change Δl of current should be for a 100 ohm resistance according to the resistor 11, i.e. R2, at a 5V voltage change, the testing result is found out by comparing the change Δl of current with the known reference value. Another method may be that the voltage change 5V directed to the component 11, i.e. resistor R2, is divided by the value of the revealed change of current, whereby the resistance of the resistor R2 obtained by the measurement is revealed, and the calculated resistance value is compared with the reference value, which in the example of FIGS. 1 to 2 would be 100 ohm.

Control and measuring according to a corresponding principle can also be done to the component 12, i.e. diode D1.

The bit string 100 and the bit string 110 over the diode D1 have a forward-direction voltage +5V, and the diode D1 conducts producing the current l2, and the current meter 60 can measure the sum current l1+l2 of the current l1 consumed by the Boundary Scan component 21 and the current l2 of the diode D1. This shows whether the diode is in place and correctly connected. On the basis of the amount of the current l2, it is possible to determine even the type of the diode, if the dependency between the current and diode type is known in advance. The current l2 is obtained by subtracting from the sum measurement l1+l2 the current l1 of the Boundary Scan component measured in the situation according to the bit string 000. The bit string 001 and the bit string 011 over the diode have a back-direction voltage, in which case the current l2 should be zero. The meter 60 then detects whether the diode D1 is correctly connected. The bit string 000 or 010 over the diode D1 has no voltage, because the same potential exists on both sides of the diode. The middle bit is not significant.

The following can be noted when examining the invention as a method. By means of the internal digital Boundary Scan control line 41 of the Boundary Scan digital component 21, a voltage-level control, for instance 0V or +5V, according to a digital logic value is provided to the connection 2 being tested comprising one or more analogue components 11, 12 at at least one point through at least one contact element 31, 33. Then the connection 2 being tested comprising one or more analogue components 11, 12 and the Boundary Scan-type digital component connected to the connection 2 are tested as a whole to measure the impact of the voltage-level control directed to the connection. Next, the measurement information is analysed and on the basis of the measurement information, one or more testing results concerning one or more analogue components of the connection are determined.

In a preferred embodiment, the process is step by step. By means of the internal digital Boundary Scan control line 41 of the Boundary Scan-type digital component 21, the connection 2 being tested is provided a voltage-level control of a first type, during which a first measurement value is measured. Then, a voltage-level control of a second type differing from the voltage-level control of the first type is provided, during which a second measurement value is measured. And finally, the obtained measurement information is analysed and one or more testing results concerning one or more analogue components are defined on the basis of the change between the measurement values. The measurement is preferably done by measuring the current. The testing result is preferably defined on the basis of the difference between the measuring values. In the method, a voltage-level control is provided to the connection being tested comprising one or more analogue components at at least two points. And in two steps so as to obtain the change, such as difference.

Even though the invention has been explained in the above with reference to an example in accordance with the accompanying drawings, it is obvious that the invention is not restricted to them but can be modified in many ways within the scope of the inventive idea disclosed in the attached claims.

1. A testing arrangement which comprises
a connection (2) to be tested comprising one or more analogue components (11, 12),
characterized in that for testing one or more analogue components of the connection (2) the testing arrangement comprises
a Boundary Scan-type digital component (21) which comprises one or more contact elements (31 to 33), and through one or more contact elements the Boundary Scan digital component (21) is connected to the connection (2) being tested so that by means of an internal digital Boundary Scan control line (41) of the Boundary Scan digital component (21) and controlled by a controller (51) in the testing arrangement, a voltage-level control according to a digital logic value can be provided to the connection (2) being tested comprising one or more analogue components in at least one location,
a measuring instrument (60) which measures the connection (2) being tested comprising one or more analogue components and the Boundary Scan-type digital component connected to the connection for the purpose of measuring the impact of the voltage-level control directed to the connection being tested, and
a means (70) for analysing the measurement information of the measuring instrument (60), which determines a testing result concerning one or more analogue components of the connection on the basis of the measurement information of the measuring instrument (60).

2. A testing arrangement as claimed in claim 1, characterized in that the controller (51) in the testing arrangement and performing the voltage-level control is an external controller outside the Boundary Scan-type digital component.

3. A testing arrangement as claimed in claim 2, characterized in that the Boundary Scan-type digital component comprises an internal controller (110) to which the internal digital Boundary Scan control line is (41) is connected, and that the internal controller (110) is connected to the external controller (51).

4. A testing arrangement as claimed in claim 1, characterized in that the controller (51) of the testing arrangement, which performs the voltage-level control, is an internal controller of the Boundary Scan-type digital component.

5. A testing arrangement as claimed in claim 1, characterized in that the internal digital Boundary Scan control line (41) of the Boundary Scan-type digital component is arranged to provide for the connection being tested a voltage-level control of a first type, during which the measuring instrument is arranged to measure a first measurement value, and that the control line is arranged to provide a voltage-level control of a second type differing from the first voltage-level control, during which second-type voltage-level control the measuring instrument is arranged to measure a second measurement value, and that the means (70) analysing the measurement information of the measuring instrument is arranged to define a testing result concerning one or more analogue components on the basis of the change between the measurement values.

6. A testing arrangement as claimed in claim 5, characterized in that the measurement value is a value of current.

7. A testing arrangement as claimed in claim 5, characterized in that the change between the measurement values is the difference in the values.

8. A testing arrangement as claimed in claim 1, characterized in that the Boundary Scan-type digital component and the connection being tested comprising one or more analogue components belong to the same functional connection entity.

9. A testing arrangement as claimed in claim 1 or 2, characterized in that the Boundary Scan digital component is on the same connection base with the connection being tested.

10. A testing arrangement as claimed in claim 1 or 2, characterized in that the Boundary Scan digital component and the connection being tested are on different connection bases.

11. A testing arrangement as claimed in claim 1, 2 or 10, characterized in that the Boundary Scan digital component is connected to the connection being tested through a coupler (600).

12. A testing arrangement as claimed in claim 1, characterized in that the coupler is a connector structure.

13. A testing arrangement as claimed in claim 1, characterized in that the Boundary Scan digital component is an integrated circuit.

14. A testing arrangement as claimed in claim 1, characterized in that at least one analogue component of the connection being tested is a passive component.

15. A testing arrangement as claimed in claim 1 or 14, characterized in that at least one analogue component of the connection being tested is a component comprising one or more semiconductor barrier layers.

16. A testing arrangement as claimed in claim 1, 14 or 15, characterized in that at least one analogue component of the connection being tested is a diode or transistor.

17. A testing arrangement as claimed in claim 1, characterized in that at least one analogue component of the connection being tested is a resistor, coil or capacitance.

18. A testing arrangement as claimed in claim 1, characterized in that the Boundary Scan, digital component is connected to the connection being tested through at least two contact elements (31, 33) so that by means of the internal digital Boundary Scan control line of the Boundary Scan digital component and controlled by the controller in the testing arrangement, a voltage-level control according to a digital logic value can be provided to the connection being tested comprising one or more analogue components in at least two locations.

19. A testing arrangement as claimed in claim 1, characterized in that the measuring instrument is a current meter.

20. A testing arrangement as claimed in claim 1, characterized in that with one voltage-level control, the measuring instrument receives for measurement a signal running through the Boundary Scan digital component.

21. A testing arrangement as claimed in claim 1, characterized in that with a second voltage-level control, the measuring instrument receives for measurement a signal running through the Boundary Scan digital component and one or more analogue components.

22. A testing method for testing a connection comprising one or more analogue components,
characterized by
using a Boundary Scan-type digital component (21) which comprises one or more contact elements (31 to 33), through which one or more contact elements, the Boundary Scan digital component (21) is connected to the connection (2) being tested,
providing by means of an internal digital Boundary Scan control line (41) of the Boundary Scan digital component (21) a voltage-level control according to a digital logic value to the connection (2) being tested comprising one or more analogue components in at least one location through at least one contact element,
measuring the connection (2) being tested comprising one or more analogue components and the Boundary Scan-type digital component (21) connected to the connection for the purpose of measuring the impact of the voltage-level control directed to the connection being tested, and
analysing the measurement information and determining one or more testing results concerning one or more analogue components of the connection on the basis of the measurement information.

23. A testing method as claimed in claim 22,
characterized in that
by means of the internal digital Boundary Scan control line of the Boundary Scan-type digital component, the connection being tested is provided a voltage-level control of a first type, during which a first measurement value is measured,
a voltage-level control of a second type differing from the voltage-level control of the first type is provided, during which a second measurement value is measured,
the obtained measurement information is analysed and one or more testing results concerning one or more analogue components are defined on the basis of the change between the measurement values.

24. A testing method as claimed in claim 22 or 23, characterized in that the measurement is performed by measuring current.

25. A testing method as claimed in claim 23, characterized in that one or more testing results concerning one or more analogue components are defined on the basis of the difference between the measurement values.

26. A testing method as claimed in claim 22, 23 or 24, characterized by providing a voltage-level control in at least two locations to the connection being tested comprising one or more analogue components.
